(19) United States
(12) Patent Application Publication
(10) Pub. No.: US 2015/0000742 A1
(43) Pub. Date: Jan. 1, 2015

(54) SOLAR CELL ABSORBER THIN FILM AND METHOD OF FABRICATING SAME

(71) Applicant: TSMC Solar Ltd., Taichung City (TW)

(72) Inventors: Chun-An Lu, Taichung City (TW); Li Xu, Taichung City (TW); Jyh-Lih Wu, Tainan City (TW)

(73) Assignee: TSMC Solar Ltd., Taichung City (TW)

(21) Appl. No.: 13/932,044

(22) Filed: Jul. 1, 2013

(51) Int. Cl. H01L 31/032; H01L 31/18

(52) U.S. Cl. CPC H01L 31/0322; H01L 31/18
USPC 136/262; 438/95; 136/264

(57) ABSTRACT

A charcopyrite-based thin film solar cell device and a method of fabricating the same is described. The solar cell includes a stacked absorber film over a substrate. The stacked absorber film includes at least two sets of absorber materials and each set includes at least three layers. At least one of the three layers includes elemental selenium and at least one of the layers includes a metal selected from the group consisting of copper, indium or gallium. The at least one selenium layer is in contact with the at least one metal layer. The at least two sets form an absorber film including multi-layer embedded selenium.

### TECHNICAL FIELD

The disclosure relates to thin film photovoltaic solar cells and methods of fabricating the same. More particularly, the disclosure relates to charcopyrite-based thin film solar cells and substructures.

### BACKGROUND

Solar cells are electrical devices for generation of electrical current from sunlight via the photovoltaic effect. Solar cell devices generally include a photovoltaically active absorber layer between lower and upper electrode layers. The absorber layer absorbs the sunlight that is converted into electrical current. Thin film solar cells are made by depositing one or more thin layers of photovoltaic material on a substrate.

In charcopyrite-based thin film solar cells, the absorber layer is made of chalcopyrite semiconductor materials, such as Cu(In,Ga)Se₂ (CIGS). The CIGS absorber layer is formed by sputtering followed by selenization with hydrogen selenide (H₂Se) gas. Cu/Ga/In or metal alloys, such as CuGa and CuGaNa, are deposited on a substrate by sputtering. Selenium is then applied in the gas phase at high temperatures to incorporate a portion of the selenium into the deposited film by absorption and diffusion.

However, the properties of the CIGS film are difficult to control using this process. In particular, it is difficult to control the composition depth profile of indium and gallium in the film, as detrimental second phases can occur during selenization and lead to low operating voltage and inconsistent device quality. Additionally, the selenization process uses reactive gas and has a long process time due to the diffusion-controlled reaction.

### BRIEF DESCRIPTION OF THE DRAWING

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like numerals denote like features throughout the specification and drawing.

FIG. 1 is a flow chart of a method of fabricating a solar cell as described herein.

FIG. 2 is a schematic cross section view of a stacked absorber film as described herein.

FIG. 3 is a schematic cross section view of a set of absorber materials for a stacked absorber film as described herein.

FIG. 4 is a schematic cross section view of a set of absorber materials for a stacked absorber film as described herein.

FIG. 5 is a schematic cross section view of a set of absorber materials for a stacked absorber film as described herein.

FIG. 6 is a schematic cross section view of a stacked absorber film as described herein.

FIG. 7A is schematic of a stacked absorber film as described herein and corresponding chart showing composition depth profile data.

FIG. 7B is a chart showing deposition profile data for a stacked absorber film as described herein.

FIG. 8A-8D are charts showing annealing profiles for methods of fabricating solar cells as described herein.

FIG. 9 is a cross section of a solar cell as described herein.

FIG. 10A is a chart showing absorber depth profile data for a stacked absorber film as described herein.

FIG. 10B is a chart showing diffraction pattern data for a stacked absorber film as described herein.

FIG. 11A is a chart showing absorber depth profile data for a conventional film.

FIG. 11B is a chart showing absorber depth profile data for a stacked absorber film as described herein.

FIG. 11C is a chart showing absorber depth profile data for a conventional film compared to a stacked absorber film as described herein.

FIG. 11D is a chart showing diffraction pattern data for a conventional film compared to a stacked absorber film as described herein.

### DETAILED DESCRIPTION

In the description, relative terms such as “lower,” “upper,” “over” “above,” “below,” “up,” “down,” “top” and “bottom” as well as derivatives thereof (e.g., “downwardly,” “upwardly,” etc.) should be construed to refer to the orientation as then described or as shown in the drawing under discussion. These relative terms are for convenience of description and do not require that the device be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

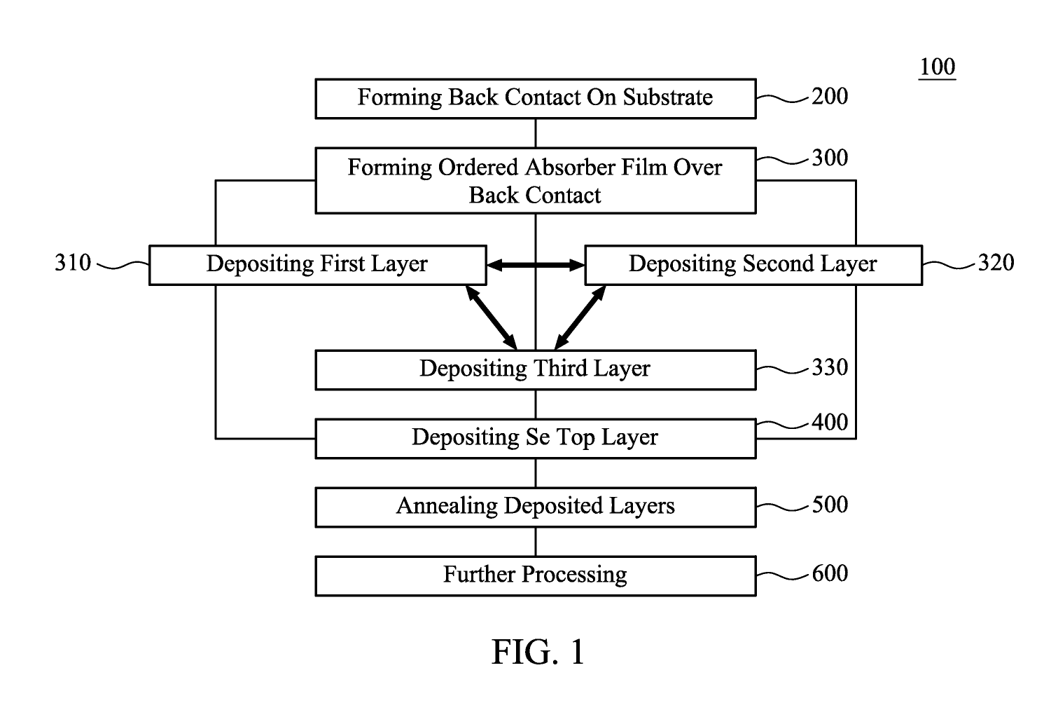

The disclosure provides for improved photovoltaic solar cell devices and methods for fabricating the devices and substructures. In particular, the disclosure provides for the controllable and repeatable formation of higher quality chalcopyrite-based absorber thin films with improved photoelectric conversion. In particular, since the chemical composition of the film can be precisely controlled, the absorber film includes an optimized depth profile and greater homogeneity, providing significantly improved device performance. An overview of the method used to form various semiconductor substructures according to the disclosure is provided in FIG. 1. Further details of the method and structures formed according to the methods are provided in conjunction with the accompanying figures.

In accordance with some embodiments, FIG. 1 is a flowchart describing a broad method 100 for fabricating a solar cell. At step 200, a back contact is formed on a substrate. The substrate can include any suitable substrate material, such as glass. In some embodiments, the substrate can include glass (e.g., soda lime glass or sodium-free (high strain point) glass) or a flexible metal foil or polymer (e.g., a polyimide). The back contact can include any suitable conductive material, such as metals and metal precursors. In some embodiments, the back contact can include molybdenum (Mo), platinum (Pt), gold (Au), silver (Ag), nickel (Ni), or copper (Cu).

Step 300 provides for the formation of a stacked absorber film over the back contact by depositing at least two sets of absorber materials. The absorber materials can include p-type semiconductors and, in particular, chalcopyrite semiconductor materials, such as Cu(In,Ga)Se₂ (CIGS). Each set of absorber materials includes at least three layers of CIGS precursor materials deposited at substeps 310, 320 and 330. In some embodiments, a thickness of each layer can range from about 10 nm to about 1 μm. In other embodiments, a thickness of each layer can range from about 100 nm to about 200 nm. The stacked absorber film is continuous, having the sets and layers in a consecutive arrangement to form the continuous film.

At least one of the three or more layers includes a metal material, such as a metal precursor. The metal material can include copper (Cu), indium (In), gallium (Ga), or combinations thereof. For example, the metal layer can include compositions such as CuGaNa (CGN), Cu—Ga (CG), (In,Ga)—Se, Cu—Se, In₂Se₃, Ga₂Se₃, In₂S₃, Ga₂S₃, CuInGa (CIG), and Cu(In,Ga)Se₂. At least one of the other layers in a set includes elemental Se, and the Se layer contacts at least one of the metal layers. As used herein, the terms “contact” and “in contact” with respect to the Se layer refer to a position of the Se layer adjacent to and above and/or below a metal layer. The layers are stacked in a sequential order to incorporate multiple selenium (Se) layers in the film, including one or more embedded Se layers (i.e. Se layers sandwiched between metal layers within the film). In some embodiments, the stacked absorber film can also include sulfur (S). For example, one or more sets 35 can have at least one layer including elemental S.

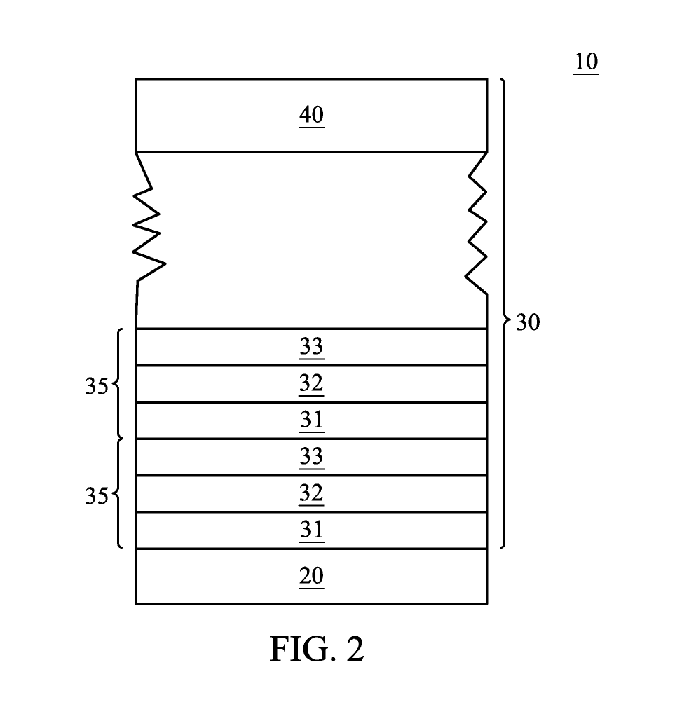

As shown in FIG. 2, the at least three layers 31, 32, 33 are deposited in sequence and form a set 35. The substeps 310, 320 and 330 shown in FIG. 1 are representative of depositing the at least three layers, and the method can include additional substeps representing additional layers forming a set. In some embodiments, a set can include at least four layers. In other embodiments, a set can include at least five layers. In other embodiments, a set can include six or more layers.

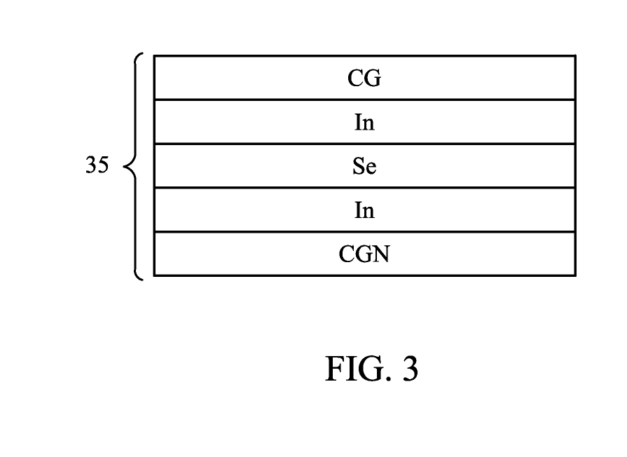

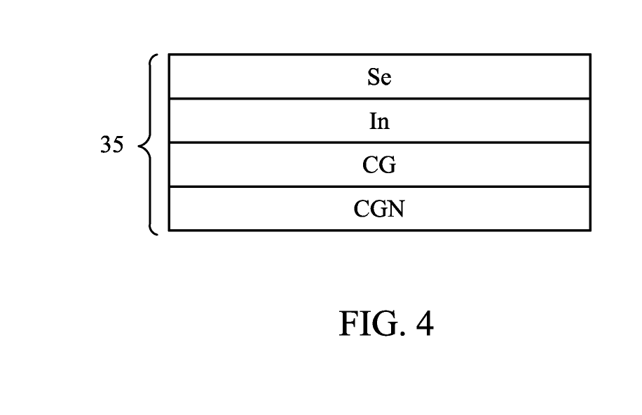

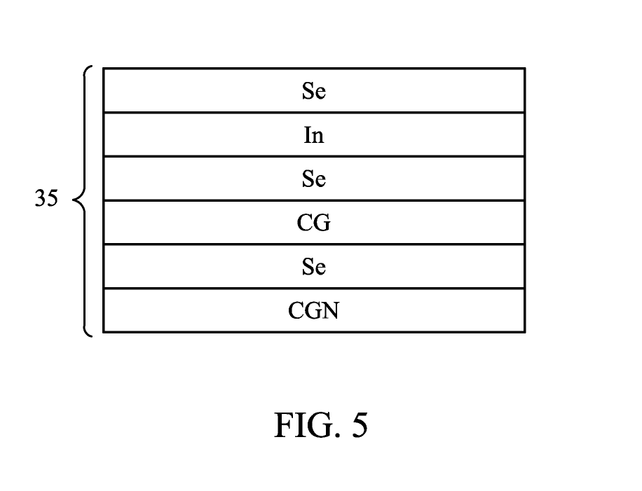

The sequence of substeps 310, et seq. can be formulated for a desired composition profile for the stacked absorber film. For example, FIGS. 3-5 show various stacking sequences for some embodiments. A set 35 can include a first metal layer deposited before a first Se layer or more than one metal layers can be deposited before a first Se layer. A set 35 can also include one Se layer or more than one Se layer. Referring to FIG. 3, in some embodiments the sequence in a set can include: (a) depositing a CGN layer, (b) depositing a first In layer over the CGN layer, (c) depositing a Se layer over the first In layer, (d) depositing a second In layer over the Se layer, and (e) depositing a CG layer over the second In layer. In other embodiments as shown in FIG. 4, the sequence in a set can include: (a) depositing a CGN layer, (b) depositing a CG layer over the CGN layer, (c) depositing an In layer over the CG layer, and (d) depositing a Se layer over the In layer. In other embodiments as shown in FIG. 5, the sequence in a set can include: (a) depositing a CGN layer, (b) depositing a first Se layer over the CGN layer, (c) depositing a CG layer over the first Se layer, (d) depositing a second Se layer over the CG layer, (e) depositing an In layer over the second Se layer, and (f) depositing a third Se layer over the In layer. In a given sequence, each successive step (b)-(e) can be completed before the previous step (a)-(d). A given sequence can also be repeated to form multiple sets 35.

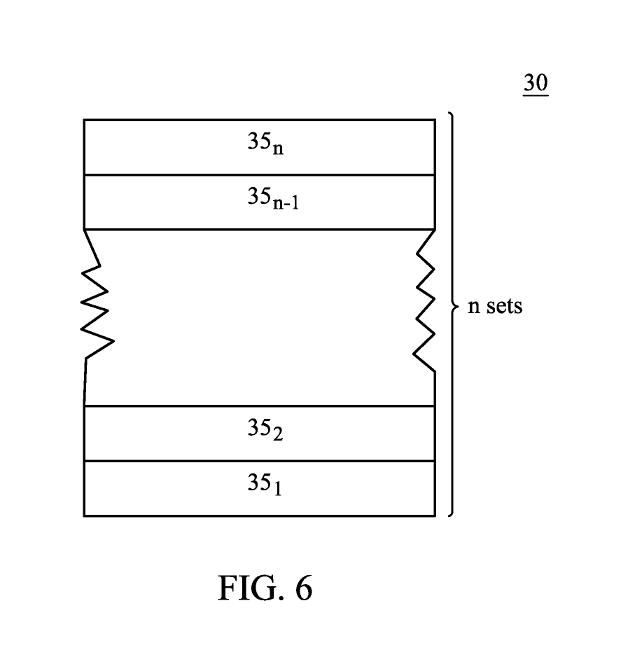

As shown in FIG. 6, multiple sets 35 are deposited to form the stacked absorber film 30. In some embodiments, the stacked absorber film 30 can include at least two sets 35. In other embodiments, the stacked absorber film 30 can include at least three sets 35. In other embodiments, the stacked absorber film 30 can include at least four sets 35. In other embodiments, the stacked absorber film 30 can include ten or more sets 35. In other embodiments, the stacked absorber film 30 can include thirty or more sets 35. In some embodiments, the stacked absorber film 30 can include a number of sets 35 ranging from 2 to 1000. In other embodiments, the stacked absorber film 30 can include more than 1000 sets 35.

The sets 35 forming the stacked absorber film 30 can be identical or can be varied to control the chemical composition of the film 30. In some embodiments, the stacked absorber film 30 can have a ratio of Cu/(Ga+In) in a range of about 0.8˜1.0. In some embodiments, the stacked absorber film 30 can have an atomic composition ratio of Ga/(Ga+In) in a range of about 0.2˜0.4. In some embodiments, the stacked absorber film 30 can have a ratio of Se/metals in a range of about 0˜3.

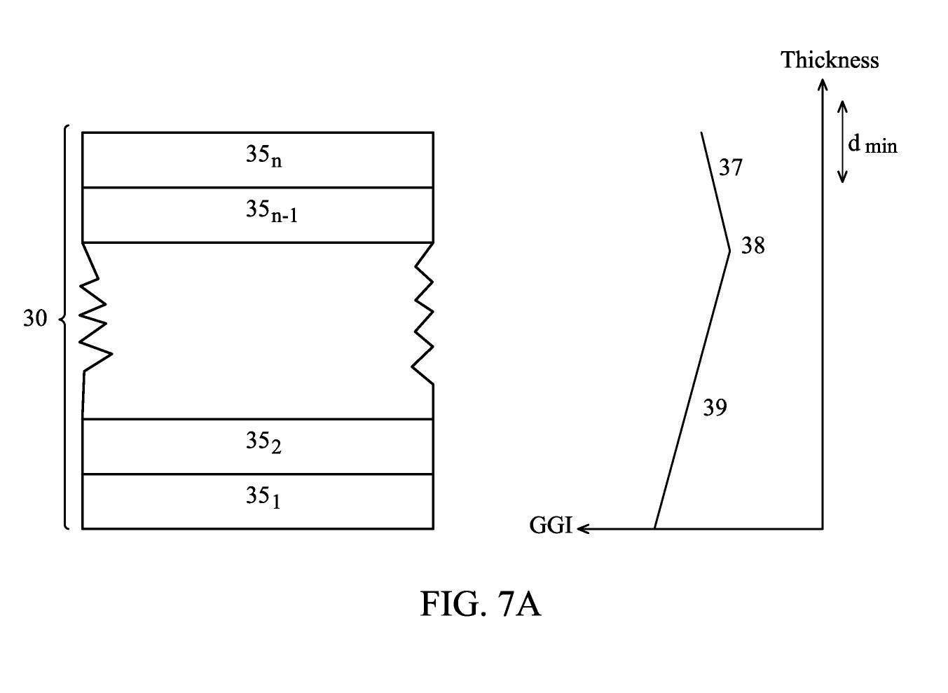

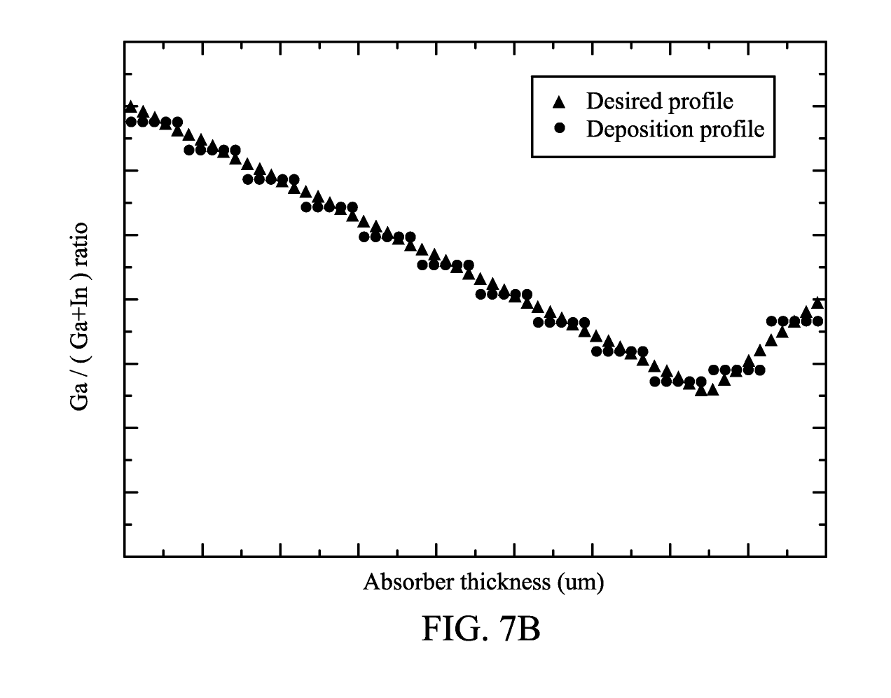

The sets 35 can also be varied to control the composition depth profile, and especially the Ga/(Ga+In) ratio, of the stacked absorber film 30. In some embodiments, the stacked absorber film 30 can include a double-gradient profile of Ga/(Ga+In). The double-gradient profile can also include a Ga/(Ga+In) ratio gradient with a positive slope in the depletion region 37 of the film 30 and a negative slope in the bulk region 39 of the film 30. FIGS. 7A and 7B show examples of double-gradient profiles of Ga/(Ga+In) in relation to absorber thickness. As shown in FIG. 7A, the turning point 38 includes the lowest Ga/(Ga+In). The distance from the surface (dₘᵢₙ) to the turning point 38 can be optimized based on the absorber properties (e.g., space charge region (SCR) width, carrier density, etc.)

In some embodiments, each of the sets 35 can include the same layer sequence and the thickness of the layers in different sets 35₁-35ₙ can be varied to achieve a desired profile. In other embodiments, the stacking sequence of the layers in different sets 35₁-35ₙ can be varied to achieve a desired profile. In other embodiments, combinations of different sequences and different layer thickness can be applied. In some embodiments as shown in FIG. 7B, the Ga/(Ga+In) ratio can be adjusted for each set to provide a stepwise profile.

The layers 31-33 can be formed using thin film deposition techniques, such as physical vapor deposition (PVD) or chemical vapor deposition (CVD). In some embodiments, PVD techniques can include sputtering, evaporation, or combinations thereof. For example, a hybrid system can be used. In some embodiments, the hybrid system can include a DC sputtering system equipped with multiple targets for the metal layers and a thermal evaporation system for the Se layers. Deposition of the absorber layers can be performed at deposition temperatures of about 300° C. or less, about 100° C. or less, about 50° C. or less, or about 25° C. or less. In some embodiments, the deposition temperature can be room temperature, e.g. about 20-25° C. As used herein, the term “about” with respect to temperature is intended to include minor deviations therefrom. For example, deviations of plus or minus 1 degree, or plus or minus 2 degrees, or plus or minus 5 degrees. Deviations may be greater for higher temperatures (e.g., greater than 100° C.), for example, plus or minus 5 degrees, or plus or minus 10 degrees.

As shown in step 400 of FIG. 1 in some embodiments, the method 100 can also include depositing a top layer including Se over the sets of absorber materials. For example, the top layer can include elemental Se. In some embodiments, a thickness of a top Se layer can be about 10 nm or more, about 20 nm or more, about 50 nm or more. In other embodiments, the thickness of the top Se layer can be greater than 50 nm.

At step 500, the deposited absorber layers are annealed at a high temperature. The maximum annealing temperatures are greater than the deposition temperature. In some embodiments, the maximum annealing temperature can be about 400° C. or more, about 450° C. or more, about 500° C. or more, about 550° C. or more, or about 600° C. or more. In other embodiments, the maximum annealing temperature can be about 600° C. or less, about 580° C. or less, or about 550° C. or less. In other embodiments, the maximum annealing temperature can range between a combination of the foregoing. For example, ranging from about 400°C. to 600° C., 400° C. to 580° C., 450° C. to 580° C., 500° C. to 580° C., 500° C. to 600° C., and 550° C. to 600° C.

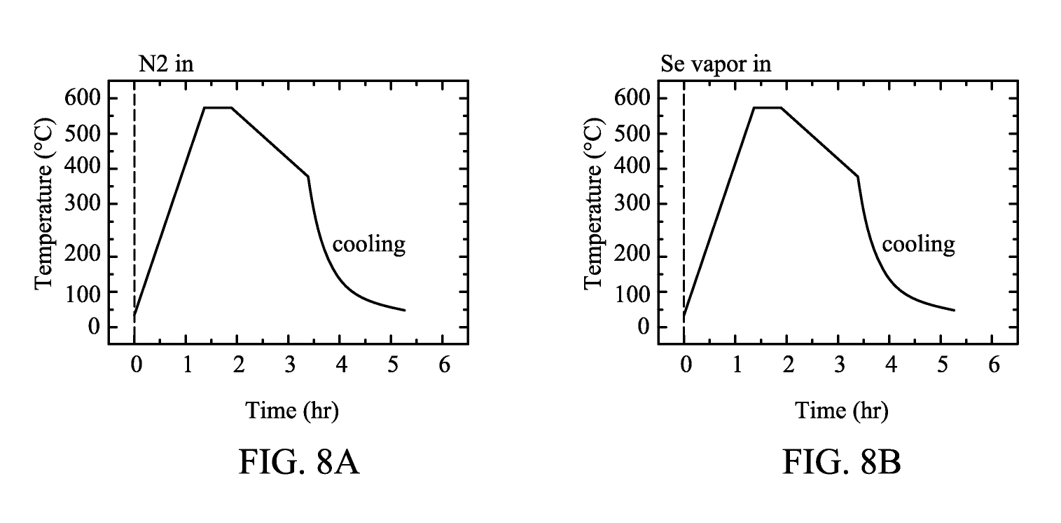

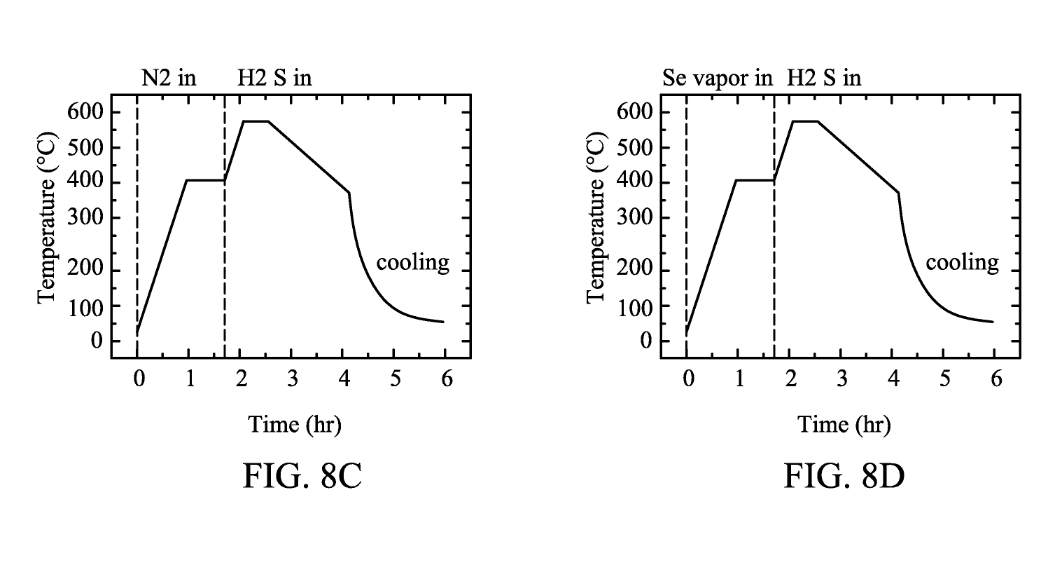

In some embodiments, the annealing process can include a ramp up period during which the temperature is raised to reach the maximum annealing temperature, a holding period during which the maximum annealing temperature is applied, a cooling period during which the temperature is lowered, or combinations thereof. For example as shown in FIGS. 8A and 8B, the annealing process for the stacked absorber film 30 can include a ramp up period, followed by a holding period, followed by a cooling period. In other embodiments as shown in FIGS. 8C and 8D, the annealing temperatures can include a first maximum temperature and a second maximum temperature. The annealing process can include a first ramp up period to reach the first maximum annealing temperature, a holding period for the first maximum annealing temperature, a second ramp up period to reach the second maximum annealing temperature, and a holding period for the second maximum annealing temperature. The cooling period can include a controlled cooling process, a natural cooling process, or both. For example as shown in FIGS. 8A-8D, the cooling period can include a controlled cooling period during which a cooling system provides a slow cooling rate to cool the substructures from a maximum annealing temperature down to a lower temperature, for example about 400° C. The controlled cooling can be followed by a natural cooling period during which the substructures are allowed to cool down naturally to a lower temperature, for example room temperature.

The annealing process can be performed under a controlled atmosphere. In some embodiments, the annealing step 500 is performed in the presence of Se vapor or one or more inert gases, e.g. nitrogen gas (N₂) or noble gases, such as argon (Ar). Sulfur can also be incorporated in the annealing step 500. For example, S vapor or hydrogen sulfide (H₂S) can also be introduced during the annealing process. The maximum annealing temperature can also be higher in the presence of a S vapor or H₂S than in the presence of a Se vapor or inert gas. For example as shown in FIG. 8C, the annealing process can include a first maximum annealing temperature in the presence of N₂ followed by a higher, second maximum annealing temperature in the presence of H₂S. In another embodiment as shown in FIG. 8D, the annealing process can include a first maximum annealing temperature in the presence of Se vapor followed by a higher, second maximum annealing temperature in the presence of H₂S.

In some embodiments at step 600, the solar cell substructure can undergo additional processing operations to complete the device and couple to other solar cells to form solar modules. For example, further processing may include forming a buffer layer over the stacked absorber film, forming a top contact over the buffer layer, and scribing interconnect lines.

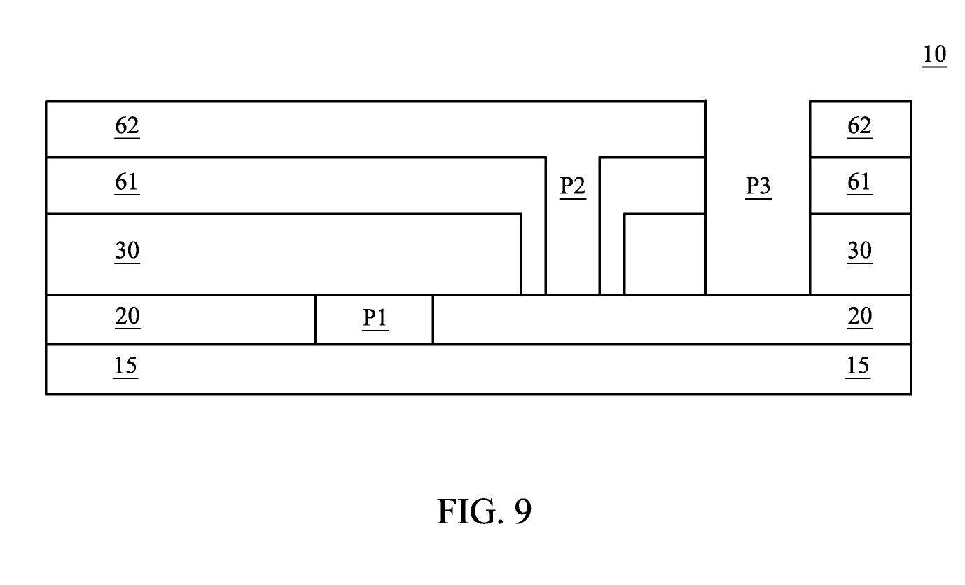

In accordance with some embodiments, FIG. 9 shows a cross-section of a solar cell 10. The solar cell 10 includes a substrate 15, a back contact 20 on the substrate 15, and a stacked absorber film 30 as described above over the back contact 20. The solar cell 10 can also include a buffer layer 61 on the stacked absorber layer 30 and a front contact layer 61 above the buffer layer 61. The solar cell 10 can also include interconnect structures comprising three scribe lines, referred to as P1, P2 and P3. The P1 scribe line extends through the back contact 20 and is filled with the stacked absorber film material 30. The P2 scribe line extends through the buffer layer 61 and the stacked absorber layer 30 and is filled with the front contact layer material 62. The P3 scribe line extends through the front contact layer 62, buffer layer 61 and stacked absorber layer 30.

Additional processing operations at step 600 may also include back end processing, module formation, and array formation. Solar cells can be coupled in series to other solar cells by respective interconnect structures to form a solar cell module. Solar cell modules can in turn be coupled to other modules in series or in parallel to form an array.

### EXAMPLES

A stacked absorber film (F01) was fabricated according to the methods described herein. A substrate of soda-lime glass was covered by a thin layer comprising molybdenum (Mo) as back contact material. The stacked absorber film layers were deposited over the Mo back contact and included 1400 sets of the following layer sequence: CGN/In/Se/In/CG. The layers were deposited by a hybrid magnetron sputtering system, including DC sputtering using

Cu, In and Ga or their combinations along with alkali metals as material for sputtering targets and a thermal evaporation system for selenium layer deposition. A rotating plate or cylindrical drum was used as the substrate holder in the sputtering system. During deposition, the thickness of each layer was controlled by the rotating speed of the holder and the deposition rate from each target and Se evaporation source. The deposited layers were annealed at a maximum temperatures greater than 500° C. to form α-CIGS, including ramping up to and holding at a first maximum temperature in the presence of N₂ then ramping up to and holding at a higher second maximum temperature in the presence of H₂S before cooling as shown in FIG. 8C.

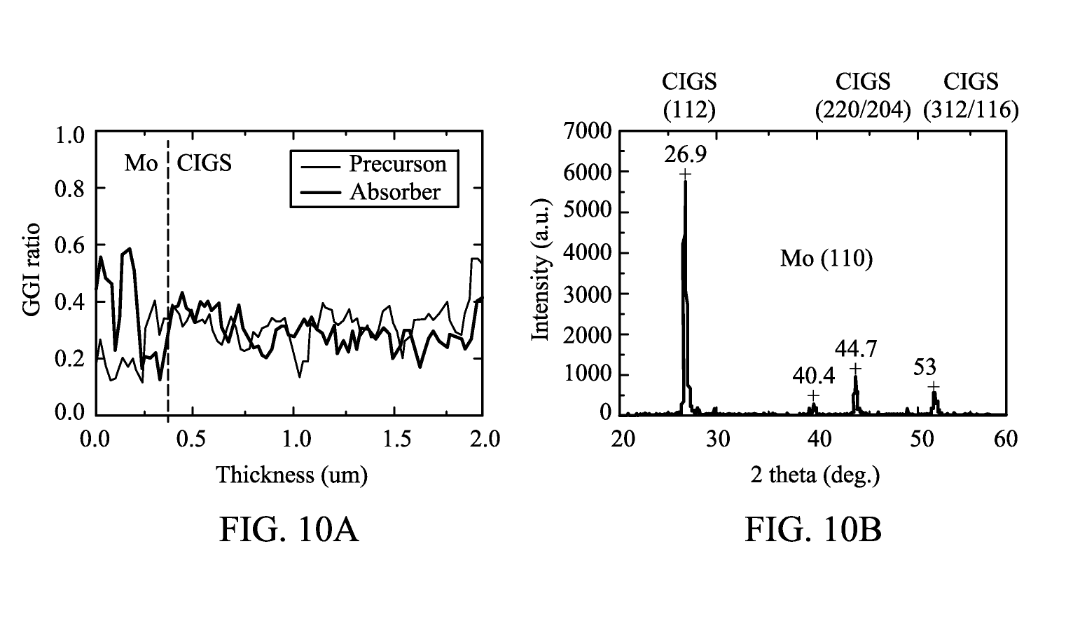

The Ga/(Ga+In) ratio relative to thickness were measured for the stacked precursor layers before annealing and for the stacked absorber film after annealing. FIG. 10A shows the Ga/(Ga+In) profiles as measured. The data indicates that the Ga/(Ga+In) profile after annealing remains constant with the precursor, e.g. Ga/(Ga+In) ratio ˜0.3). The properties of the F01 film were also measured by x-ray diffraction (XRD) and FIG. 10B shows the XRD peak analysis. The XRD (112) peak position indicates that the phase for the F01 film is Cu(In_{0.7}Ga_{0.3})Se₂.

For comparison, another stacked absorber film (F02) was fabricated according to the methods described herein. A thin layer of Mo back contact material was deposited on a glass substrate. The stacked absorber film layers were deposited on and included 35 sets of CGN/In/Se/In/CG were deposited on the back contact by a hybrid sputtering system. A conventional absorber film (F03) was also fabricated using a two-step process. First, several layers of CGN, followed by several layers of CG, followed by several layers of In were deposited on a Mo-coated glass substrate by a sputtering technique. Both the F02 and F03 absorber layers were annealed at a first temperature in a H₂Se reactive gas atmosphere, then at a higher second temperature in the presence of H₂S gas, followed by cooling.

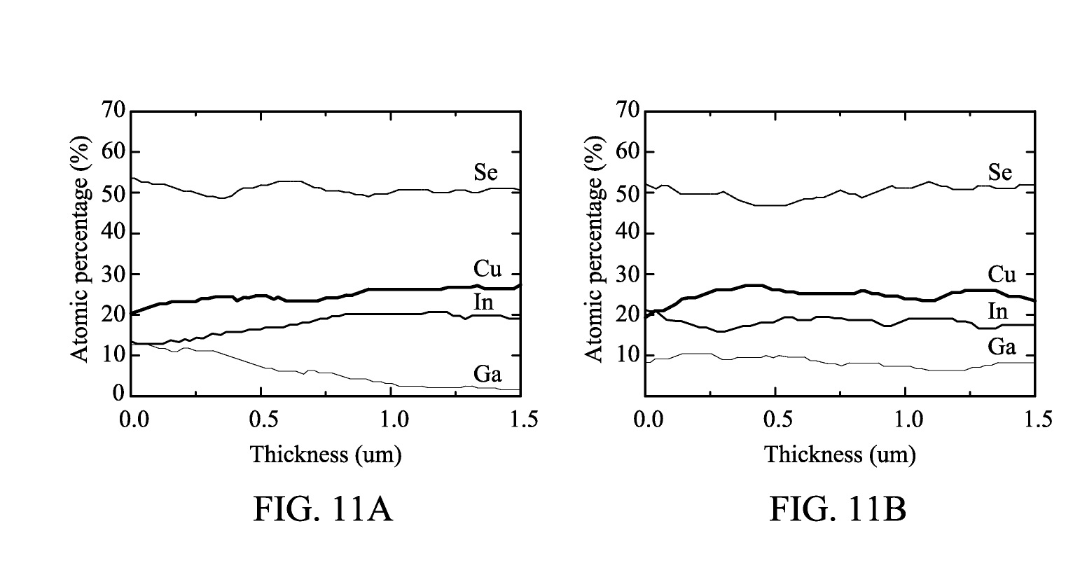

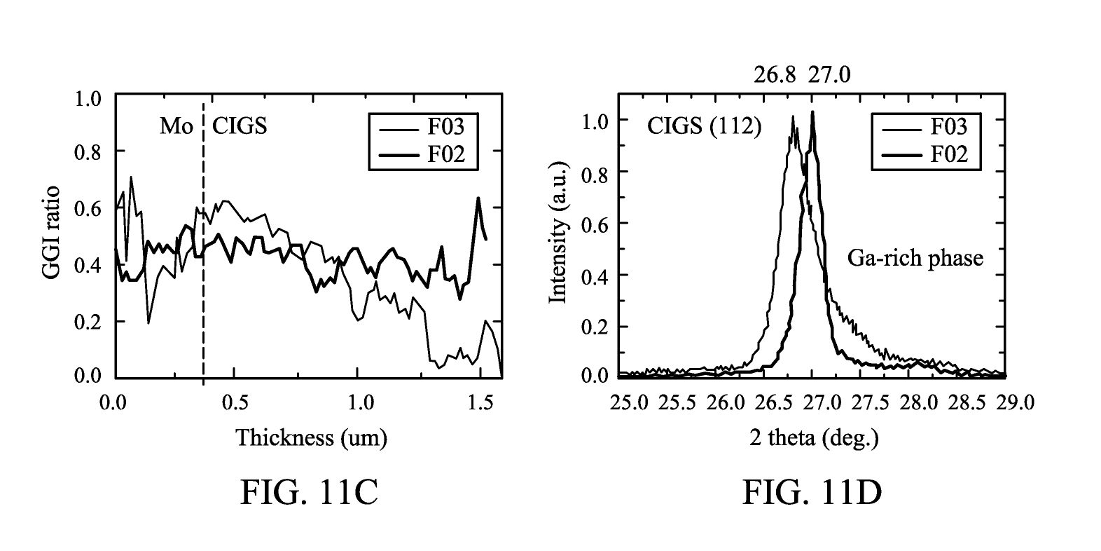

The properties of the F02 and F03 films were measured by energy-dispersive X-ray spectroscopy (EDX) and XRD. FIG. 11A shows the EDX line scans for the F03 film, indicating inconsistency in the atomic percentage of the materials and, in particular, inter-diffusion of In and Ga. By comparison, FIG. 11B shows the EDX line scans for the F02 film, indicating that the F02 stacked absorber film avoids unwanted second phases and provides better homogeneity in the film. The Ga/(Ga+In) profile for the F02 film after annealing more closely resembles the profile of the as-deposited layers of CIGS materials before annealing than the F03 film. FIG. 11C shows the EDX profiles and FIG. 11D shows the XRD analysis for the F02 and F03 films. The XRD (112) peak position and EDX profile indicate that the F03 process has less Ga-incorporation at surface and phase segregation compared with the F02 process forming a stacked absorber film.

Device performance was also compared. The V_{OC} of the F03 film measured at 626 mV and V_{OC} of the F02 stacked absorber film measured at 681 mV. The F02 film demonstrated a higher V_{OC} due to its improved Ga/(Ga+In) ratio profile.

In summary, the disclosed methods provide a controllable and effective method for fabricating solar cells and solar cell substructures with higher quality absorber films. The stacked absorber film according to the disclosure provides greater precision in the composition of the In and Ga profiles in the film, resulting in higher operating voltage. The controllable fabrication process also leads to a better repeatability and yield. Additionally, the efficient and effective methods eliminate the need for reactive H₂Se gas, thus reducing the process time. As such, the disclosed methods can reduce manufacturing costs while providing improved throughput and stability in the process.

Although particular examples are described above with respect to CIGS, the structures and methods described herein can be applied to a variety of chalcopyrite-based thin film solar cells, such as CuInSe₂ (CIS), CuGaSe₂ (CGS), Cu(In,Ga)Se₂ (CIGS), Cu(In,Ga)(Se,S)₂ (CIGSS), and the like. For example, the structures and methods described herein can be applied to thin films formed from combinations of I-III-VI compounds including the following elements:

| I elements | III elements | VI elements |
|---|---|---|
| Cu | In | Se |
| Ag | Ga | S |
| | Al | Te |

In particular, the structures and methods can also be applied when Cu is replaced by Ag, and when In or Ga is replaced by Al.

In some embodiments, a method for fabricating a solar cell is provided. The method can include forming a back contact on a substrate and forming a stacked absorber film over the back contact by depositing at least two sets of absorber materials, each set including at least three layers. At least one of the layers includes elemental Se; at least one of the layers includes a metal selected from the group consisting of Cu, In or Ga; and the at least one Se layer contacts the at least one metal layer.

In some embodiments, at least two of the layers in each set include one or more metals selected from the group consisting of Cu, In or Ga.

In some embodiments, the stacked absorber film has a ratio of Cu/(Ga+In) in a range of about 0.8˜1.0.

In some embodiments, the stacked absorber film has a ratio of Ga/(Ga+In) in a range of about 0.2˜0.4.

In some embodiments, the stacked absorber film has a ratio of Se/metals in a range of about 0˜3.

In some embodiments, the at least one metal layer includes CGN, CG, In, (In,Ga)—Se, or Cu—Se.

In some embodiments, at least one layer includes elemental S.

In some embodiments, the depositing step includes a hybrid process in which the at least one metal layer is deposited by sputtering and the at least one Se layer is deposited by evaporation.

In some embodiments, the method also includes ordering the layers to form a double gradient profile of Ga/(Ga+In) in the stacked absorber film.

In some embodiments, the method also includes depositing a top layer of elemental Se over the sets of absorber materials.

In some embodiments, the method also includes annealing the deposited absorber layers at a temperature of about 400° C. or greater.

In some embodiments, the annealing step is performed in the presence of an inert gas or elemental Se vapor.

In some embodiments, the annealing step also includes introducing elemental S vapor or H₂S gas.

In some embodiments, a method for fabricating a solar cell is provided. The method can include providing a substrate with a back contact on the substrate; depositing a first layer including metal selected from the group consisting of Cu, In or Ga above the back contact; depositing above the first layer another layer including metal selected from the group consisting of Cu, In or Ga and having a different composition from the first layer; depositing a layer including elemental Se above the back contact, wherein the Se layer is in contact with at least one of the metal layers; and repeating the depositing steps in a sequence to form a stacked absorber film on the back contact.

In some embodiments, the depositing steps are performed in a sequence including, in order: (a) depositing a CGN layer; (b) depositing a first In layer over the CGN layer; (c) depositing a Se layer over the first In layer; (d) depositing a second In layer over the Se layer; and (e) depositing a CG layer over the second In layer.

In some embodiments, the depositing steps are performed in a sequence including, in order: (a) depositing a CGN layer; (b) depositing a CG layer over the CGN layer;

(c) depositing an In layer over the CG layer; and (d) depositing a Se layer over the In layer.

In some embodiments, the depositing steps are performed in a sequence including, in order: (a) depositing a CGN layer; (b) depositing a first Se layer over the CGN layer; (c) depositing a CG layer over the first Se layer; (d) depositing a second Se layer over the CG layer; (e) depositing an In layer over the second Se layer; and (f) depositing a third Se layer over the In layer.

In some embodiments, a solar cell is provided. The solar cell includes a stacked absorber film over a substrate. The stacked absorber film can include at least two sets of absorber materials, each set including at least three layers. At least one of the layers can include elemental Se; at least one of the layers can include a metal selected from the group consisting of Cu, In or Ga; and the at least one Se layer contacts the at least one metal layer.

In some embodiments, the solar cell also includes a back contact between the substrate and the stacked absorber film, a buffer layer over the stacked absorber film, and a front contact over the buffer layer.

In some embodiments, the stacked absorber film includes a double gradient profile of Ga/(Ga+In). The gradient profile has a positive slope in a depletion region of the film and a negative slope in a bulk region of the film.

The descriptions of the fabrication techniques for exemplary embodiments may be performed using any suitable commercially available equipment commonly used in the art to manufacture solar cell devices, or alternatively, using future developed equipment and techniques.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. A method for fabricating a solar cell, comprising:
forming a back contact on a substrate; and
forming a stacked absorber film over said back contact by depositing at least two sets of absorber materials, each set comprising at least three layers wherein:
at least one of said layers comprises elemental Se,
at least one of said layers comprises a metal selected from the group consisting of Cu, In or Ga, and
said at least one Se layer contacts said at least one metal layer.

2. The method as in claim 1, wherein at least two of said layers in each set comprise one or more metals selected from the group consisting of Cu, In or Ga.

3. The method as in claim 1, wherein said stacked absorber film has a ratio of Cu/(Ga+In) in a range of about 0.8˜1.0.

4. The method as in claim 1, wherein said stacked absorber film has a ratio of Ga/(Ga+In) in a range of about 0.2˜0.4.

5. The method as in claim 1, wherein said stacked absorber film has a ratio of Se/metals in a range of about 0˜3.

6. The method as in claim 1, wherein said at least one metal layer comprises CGN, CG, In, (In,Ga)—Se, or Cu—Se.

7. The method as in claim 1, wherein at least one layer includes elemental S.

8. The method as in claim 1, wherein said depositing step comprises a hybrid process wherein said at least one metal layer is deposited by sputtering and said at least one Se layer is deposited by evaporation.

9. The method as in claim 1, further comprising ordering said layers to form a double gradient profile of Ga/(Ga+In) in said stacked absorber film.

10. The method as in claim 1, further comprising depositing a top layer of elemental Se over said sets of absorber materials.

11. The method as in claim 1, further comprising annealing said deposited absorber layers at a temperature of about 400° C. or greater.

12. The method as in claim 11, wherein said annealing step is performed in the presence of an inert gas or elemental Se vapor.

13. The method as in claim 11, wherein said annealing step further comprises introducing elemental S vapor or H₂S gas.

14. A method for fabricating a solar cell, comprising:
providing a substrate with a back contact on said substrate;
depositing a first layer comprising metal selected from the group consisting of Cu, In or Ga above the back contact;
depositing above said first layer another layer comprising metal selected from the group consisting of Cu, In or Ga and having a different composition from said first layer;
depositing a layer comprising elemental Se above the back contact, wherein said Se layer is in contact with at least one of said metal layers; and
repeating said depositing steps in a sequence to form a stacked absorber film on said back contact.

15. The method as in claim 14, wherein said depositing steps are performed in a sequence comprising, in order:
(a) depositing a CuGaNa (CGN) layer;
(b) depositing a first In layer over said CGN layer;
(c) depositing a Se layer over said first In layer;
(d) depositing a second In layer over said Se layer; and
(e) depositing a CG layer over said second In layer.

16. The method as in claim 14, wherein said depositing steps are performed in a sequence comprising, in order:
(a) depositing a CGN layer;
(b) depositing a CG layer over said CGN layer;
(c) depositing an In layer over said CG layer; and
(d) depositing a Se layer over said In layer .

17. The method as in claim 14, wherein said depositing steps are performed in a sequence comprising, in order:
(a) depositing a CGN layer;
(b) depositing a first Se layer over said CGN layer;
(c) depositing a CG layer over said first Se layer;
(d) depositing a second Se layer over said CG layer;
(e) depositing an In layer over said second Se layer; and
(f) depositing a third Se layer over said In layer.

18. A solar cell comprising a stacked absorber film over a substrate, said stacked absorber film comprising at least two sets of absorber materials, each set comprising at least three layers wherein:
at least one of said layers comprises elemental Se;
at least one of said layers comprises a metal selected from the group consisting of Cu, In or Ga; and
said at least one Se layer contacts said at least one metal layer.

19. The solar cell as in claim 18, further comprising a back contact between said substrate and said stacked absorber film, a buffer layer over said stacked absorber film, and a front contact over said buffer layer.

20. The solar cell as in claim 19, wherein said stacked absorber film comprises a double gradient profile of Ga/(Ga+In), wherein said gradient profile has a positive slope in a depletion region of said film and a negative slope in a bulk region of said film.
